(19) United States
(12) Patent Application Publication
(10) Pub. No.: US 2011/0036389 A1
(43) Pub. Date: Feb. 17, 2011

(54) CTE MODULATED ENCAPSULANTS FOR SOLAR MODULES

(75) Inventors: Kedar Hardikar, San Jose, CA (US); Todd Krajewski, Mountain View, CA (US); Kent Whitfield, Mountain View, CA (US)

Correspondence Address: Weaver Austin Villeneuve & Sampson LLP-MSOL;Attn: MIASOLE, P.O. Box 70250, Oakland, CA, 94612-0250, US

(73) Assignee: MIASOLE, Santa Clara, CA (US)

(21) Appl. No.: 12/539,054

(22) Filed: Aug. 11, 2009

(51) Int. Cl. H01L 31/048; C03C 27/12

(52) U.S. Cl. 136/251; 156/99

(57) ABSTRACT

A photovoltaic module having a light transmissive front layer, a back layer, and a plurality of interconnected photovoltaic cells disposed between the light transmissive front layer and the back layer has a CTE-modified composite encapsulant is interposed between the plurality of solar cells and the light transmissive front layer. The composite encapsulant includes a bulk encapsulant transmissive to visible and near visible wavelengths of the solar spectrum and having a base coefficient of thermal (CTE) expansion, and an encapsulant CTE modifier in the bulk encapsulant. The encapsulant CTE modifier is substantially evenly distributed through the composite encapsulant thickness and interacts with the bulk encapsulant to reduce the effective CTE of the composite encapsulant below that of the bulk encapsulant.

### BACKGROUND OF THE INVENTION

Photovoltaic cells are widely used for generation of electricity, with multiple photovoltaic cells interconnected in module assemblies. Such modules may in turn be arranged in arrays and integrated into building structures or otherwise assembled to convert solar energy into electricity by the photovoltaic effect. Individual modules are encapsulated to protect the module components from the environment. Encapsulant materials on the light-incident side of the cells are ideally highly transmissive to the energy generating solar spectrum and rigorous enough to reliably function through module manufacturing, testing and operation.

### SUMMARY OF THE INVENTION

The present invention provides a photovoltaic module encapsulant that addresses module reliability challenges relating to the issue of dimensional changes of the encapsulant due to changes in temperature. Such temperature changes can occur during product manufacturing, and in particular, a photovoltaic module can experience temperatures extremes during testing and in its normal operating environment. It has been found that significant dimensional changes in the encapsulant attributable to these temperature changes can cause in delamination of the module, degrading module electrical performance and safety. Use of an encapsulant that is less subject to temperature-based dimensional changes improves module safety and performance.

One aspect of the invention relates to a photovoltaic module having a light transmissive front layer, a back layer, and a plurality of interconnected photovoltaic cells disposed between the light transmissive front layer and the back layer. A composite encapsulant is interposed between the plurality of solar cells and the light transmissive front layer. The composite encapsulant includes a bulk encapsulant that transmits light in the visible and near visible wavelengths of the solar spectrum and having a base coefficient of thermal (CTE) expansion, and an encapsulant CTE modifier in the bulk encapsulant. The encapsulant CTE modifier is substantially evenly distributed through the composite encapsulant thickness and interacts with the bulk encapsulant to reduce the effective CTE of the composite encapsulant below that of the bulk encapsulant.

Another aspect of the invention relates to a method of making a photovoltaic module. The method involves assembling a light transmissive front layer, a back layer, a plurality of interconnected photovoltaic cells disposed between the light transmissive front layer and the back layer. A composite encapsulant is disposed between the plurality of solar cells and the light transmissive front layer. The assembled module is then laminated. The composite encapsulant includes a bulk encapsulant that transmit light in the visible and near visible wavelengths of the solar spectrum and having a base coefficient of thermal (CTE) expansion, and an encapsulant CTE modifier in the bulk encapsulant. The encapsulant CTE modifier is substantially evenly distributed through the composite encapsulant thickness and interacts with the bulk encapsulant to reduce the effective CTE of the composite encapsulant below that of the bulk encapsulant.

These and other aspects of the invention are described further below with reference to the figures.

### BRIEF DESCRIPTION OF THE DRAWINGS

FIG. 1 shows a cross-sectional view of certain components of a photovoltaic module in accordance with the present invention.

FIG. 2 depicts a process flow showing certain operations in a process of forming a photovoltaic module in accordance with the present invention.

### DETAILED DESCRIPTION

Reference will now be made in detail to specific embodiments of the invention. Examples of the specific embodiments are illustrated in the accompanying drawings. While the invention will be described in conjunction with these specific embodiments, it will be understood that it is not intended to limit the invention to such specific embodiments. On the contrary, it is intended to cover alternatives, modifications, and equivalents as may be included within the spirit and scope of the invention. In the following description, numerous specific details are set forth in order to provide a thorough understanding of the present invention. The present invention may be practiced without some or all of these specific details. In other instances, well known mechanical apparatuses and/or process operations have not been described in detail in order not to unnecessarily obscure the present invention.

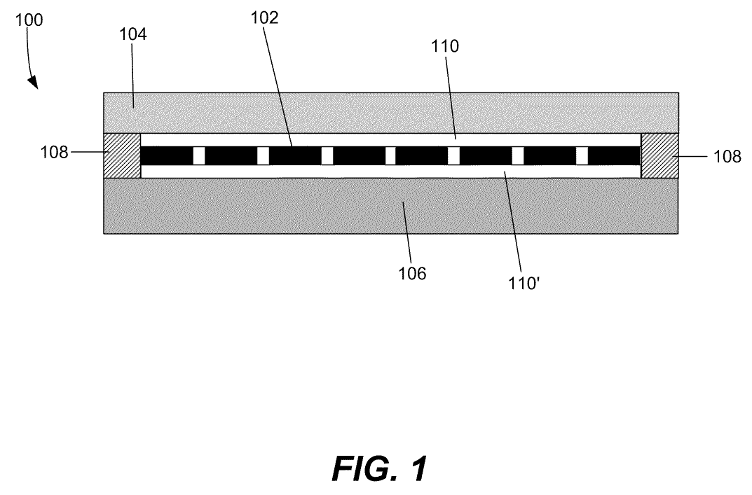

Embodiments of the present invention relate to encapsulation of photovoltaic modules (also referred to as solar modules). FIG. 1 shows a not-to-scale cross-sectional view of certain components of a solar module 100 in accordance with one embodiment of the present invention. The module 100 includes interconnected solar cells 102 and front (light-incident) and back layers 104 and 106, respectively, for environmental protection and mechanical support. A thermoplastic polymer encapsulant 110 is also provided between the solar cells 102 and at least the front layer 104 to provide electrical insulation and further protection to the underlying solar cells by preventing direct contact between the solar cells and the generally rigid front layer 104. In some instances, the same or a different encapsulant layer 110′ may also be provided between the solar cells 102 and the back layer 106 for the same reasons. In certain modules, an additional material 108 surrounds the solar cells 102, and in this example, is embedded within encapsulating layers 110 and 110′. In certain modules, a frame (not shown) engages the module edges and surrounds the module 100 for mechanical support.

The front and back layers may be any suitable material that provides the environmental protection and mechanical support required for reliable module operation. Typically, the front and back layers are rigid plates, light transmitting in the case of the front layer, such as glass, although other materials, such as polymers, multi-layer laminates and metals that meet the functional requirements may also be used.

The front, light-incident layer 104 should transmit visible and near visible wavelengths of the solar spectrum and be chemically and physically stable to anticipated environmental conditions, including solar radiation, temperature extremes, rain, snow, hail, dust, dirt and wind to provide protection for the module contents below. A glass plate comprising any suitable glass including conventional and float glass, tempered or annealed glass or combinations thereof or with other glasses is preferred in many embodiments. The total thickness of a suitable glass or multi-layer glass layer 104 may be in the range of about 2 mm to about 15 mm, optionally from about 2.5 mm to about 10 mm, for example about 3 mm or 4 mm. As noted above, it should be understood that in some embodiments, the front layer 104 may be made of a non-glass material that has the appropriate light transmission, stability and protective functional requirements. The front layer 104, whether glass or non-glass, transmits light in a spectral range from about 400 nm to about 1100 nm. The front layer 104 may not necessarily, and very often will not, transmit all incident light or all incident wavelengths in that spectral range equally. For example, a suitable front layer is a glass plate having greater than 50% transmission, or even greater than 80% or 90% transmission from about 400-1100 nm. In some embodiments, the front layer 104 may have surface treatments such as but not limited to filters, anti-reflective layers, surface roughness, protective layers, moisture barriers, or the like. Although not so limited, in particular embodiments the front layer 104 is a tempered glass plate about 3 mm thick.

The back layer 106 is also typically a glass plate, but its composition is not so limited. The back layer 106 may be the same as or different than the front layer 104. Since the back layer 106 does not have the same optical constraints as the front layer 106, it may also be composed of materials that are not optimized for light transmission, for example metals and/or polymers.

The material 108 may be an organic or inorganic material that has a low inherent water vapor transmission rate (WVTR) (typically less than 1-2 g/m²/day) and, in certain embodiments may absorb moisture and/or prevent its incursion. In one example, a butyl-rubber containing moisture getter or desiccant is used.

The solar cells 102 may be any type of photovoltaic cell including crystalline and thin film cells such as, but not limited to, semiconductor-based solar cells including microcrystalline or amorphous silicon, cadmium telluride, copper indium gallium selenide or copper indium selenide, dye-sensitized solar cells, and organic polymer solar cells. In particular embodiments, the cells are copper indium gallium selenide cells.

The encapsulant 110 interposed between the plurality of solar cells 102 and the light transmissive front layer 104 provides electrical insulation and further protection to the underlying solar cells 102 by preventing direct contact between the solar cells and the generally rigid front layer 104. A suitable encapsulant 110 is a thermoset encapsulant, generally a thermoplastic polymer material. The thickness of the encapsulant between the front layer and the solar cells may be from about 10 to 1000 microns, or about 25 to 700 microns, for example about 600 microns.

Conventional encapsulants are low modulus, materials that have a much higher coefficient of thermal expansion (CTE) than the encapsulated module components with which they are laminated in the module. Computational modeling has shown that the high CTE of conventional encapsulants causes high stresses in the vicinity of encapsulated components as the thermoplastic material stiffens during cooling. This is believed to contribute to delamination, resulting in lower module reliability.

Computational modeling has further indicated that that peak stresses driving reliability failures can be lowered by changing the CTE of the encapsulant. The present invention provides a composite encapsulant including a bulk encapsulant, such as, but not limited to, conventional thermoplastic polymer encapsulant materials used in solar modules, reinforced with a second material with a lower coefficient of thermal expansion than the bulk encapsulant. When the second material, referred to as an encapsulant CTE modifier, is combined with the bulk encapsulant the effective CTE of the resulting reinforced polymer composite encapsulant is reduced relative to the CTE of the bulk encapsulant. As a result, thermal stresses in the in the solar module and reduced and reliability is enhanced.

Modeling shows that the effective CTE of a reinforced polymer, that is, the CTE of the composite, varies as follows:

$${α}_{c} \approx {α}_{p} ( 1 - {v}_{f} ) + {α}_{f} {v}_{f}$$

$$\frac{{α}_{c}}{{α}_{p}} \approx ( 1 - {v}_{f} ) + \frac{{α}_{f}}{{α}_{p}} {v}_{f}$$

Where, α_{c} is the composite effective CTE, αₚ is the CTE of the bulk material, α_{f} is the CTE of the second material (reinforcement) and v_{f} is the volume fraction of the reinforcement. Due to low values of α_{f} relative to αₚ, effective change is similar to the volume fraction. Thus, the effective CTE is expected to vary approximately linear with volume fraction of the composite constituents for a uniformly distributed non-woven second material. A similar relationship applies for woven second materials. Suitable bulk encapsulants are transmit light in the visible and near visible wavelengths of the solar spectrum and form a durable, electrically insulating seal between the solar cells and the light transmissive front layer, generally glass. In many embodiments, encapsulants are polymers, in particular thermoplastic polymers. Examples include non-olefin thermoplastic polymers or thermal polymer olefin (TPO). Particular examples include, but are not limited to, polyethylene, polypropylene, polybutylene, polyethylene terephthalate (PET), polybutylene terephthalate (PBT), polystyrene, polycarbonates, fluoropolymers, acrylics, ionomers, silicones and combinations thereof. In some embodiments the bulk encapsulant is a polyethylene, in particular a linear, low density polyethylene, for example Z68, a linear, low density polyethylene available from Dai Nippon Printing (DNP). Other suitable bulk encapsulants include various SURLYN® thermoplastic ionomeric resin grades (e.g., PV4000 or equivalent), and SENTRY GLASS® laminate interlayer available from DuPont, and GENIOMER® 145 thermoplastic silicone elastomer available from Wacker Chemie.

An encapsulant 110 in accordance with the present invention also includes a CTE modifier added to the bulk encapsulant. The encapsulant CTE modifier has a lower CTE than the bulk encapsulant and does not substantially alter the optical properties of the bulk encapsulant. That is, it also transmits light in the visible and near visible wavelengths of the solar spectrum, particularly when combined with the bulk encapsulant. When a suitable encapsulant CTE modifier is combined with the bulk encapsulant the encapsulant CTE modifier interacts with the bulk encapsulant such that the effective CTE of the resulting composite is reduced relative to the CTE of the bulk encapsulant. In some embodiments, the encapsulant CTE modifier comprises at least 25%, or at least 30%, by weight of the composite encapsulant constituents. In some embodiments, the effective CTE of the composite encapsulant is at least 25% less than that of the bulk encapsulant, or at least 50% less than that of the bulk encapsulant. In some embodiments, the effective CTE of the composite encapsulant is within 25% of the front layer CTE, e.g., glass plate.

Suitable encapsulant CTE modifiers include, but are not limited to, glass, high modulus polyimide, linear high molecular weight polyethylene, light transmissive minerals, liquid crystal polymers, and combinations thereof.

The encapsulant CTE modifier is substantially evenly distributed through the composite encapsulant thickness. By substantially evenly distributed through the composite encapsulant thickness it is meant that the distribution profile of the encapsulant CTE modifier is about the same through the thickness of the upper and lower halves of the composite encapsulant. It is not merely applied to or otherwise concentrated on one side or the other of the bulk encapsulant. The substantially even distribution of encapsulant CTE modifier through the composite encapsulant thickness can be accomplished in many ways. In various embodiments, the encapsulant CTE modifier may comprise fibers or particles. In various embodiments, the encapsulant CTE modifier may be a woven (e.g., mesh) or non-woven (e.g., felt or discrete fibers or particles), or a combination thereof. In various embodiments, the encapsulant CTE modifier is substantially uniformly distributed through at least 50%, or at least 75%, of the composite encapsulant thickness. In various embodiments, the encapsulant CTE modifier is distributed substantially uniformly throughout the bulk encapsulant.

In certain embodiments where a woven encapsulant CTE modifier is used, the woven encapsulant CTE modifier is embedded in the bulk encapsulant to form the composite. To the extent that the thickness of the woven encapsulant CTE modifier is not co-extensive with the thickness of the composite, the woven encapsulant CTE modifier is embedded such that it is substantially evenly distributed through the composite encapsulant thickness, such as in the middle of the overall composite thickness with unmodified bulk encapsulant at the outer surfaces. In such embodiments, the CTE modification benefit of the invention may be achieved to at least some extent throughout the thickness of the encapsulant. Similarly, composite encapsulants having non-woven fibrous or particulate encapsulant CTE modifiers may be configured in this way.

In some preferred embodiments, the encapsulant CTE modifier is distributed substantially uniformly throughout the bulk encapsulant. For example, the encapsulant CTE modifier may comprise non-woven fibers or particles that are thoroughly mixed with a bulk encapsulant to form the composite encapsulant. In some such embodiments, the encapsulant CTE modifier is a non-woven glass fiber. In some such embodiments, the module's light transmissive front layer comprises glass, the bulk encapsulant comprises liner low density polyethylene and the encapsulant CTE modifier comprises non-woven glass fiber.

Another aspect of the present invention involves the use of adhesion promoters to enhance bonding between the bulk encapsulant and the encapsulant CTE modifier. A number of materials are known to promote bonding between materials identified herein as suitable for bulk encapsulants and encapsulant CTE modifiers. Such materials can be incorporated into bulk encapsulants such that a bulk encapsulant comprises an adhesion promoter to enhance bonding to an encapsulant CTE modifier. For example, siloxane may be incorporated into a bulk thermoplastic polymer encapsulant to promote adhesion to a glass encapsulant CTE modifier, such as glass fiber. Additionally, or alternatively, an encapsulant CTE modifier may be treated to enhance bonding to a bulk encapsulant. For example, a glass encapsulant CTE modifier may be silynized to enhance bonding to a bulk thermoplastic polymer encapsulant.

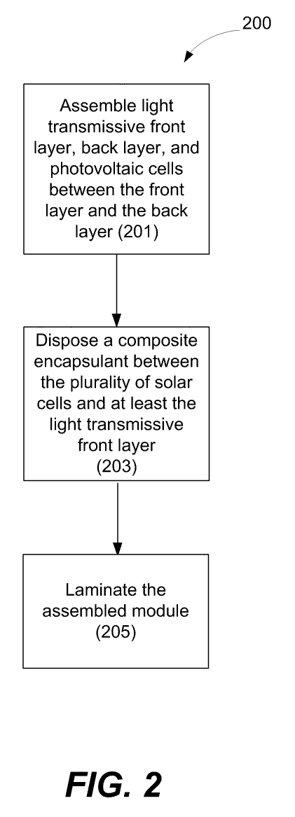

Another aspect of the invention is a method of making a photovoltaic module. FIG. 2 depicts a process flow 200 showing certain operations in a process of forming a photovoltaic module in accordance with the present invention. A light transmissive front layer, a back layer, and a plurality of interconnected photovoltaic cells disposed between the light transmissive front layer and the back layer are assembled (201). In this or another operation, a composite encapsulant is disposed between the plurality of solar cells and at least the light transmissive front layer (203). The assembled module is then laminated (205).

The composite encapsulant includes a bulk encapsulant that transmits light in the visible and near visible wavelengths of the solar spectrum (for example, greater than 50% transmission, or even greater than 80% transmission from about 400-1100 nm) and have a base coefficient of thermal (CTE) expansion, and an encapsulant CTE modifier in the bulk encapsulant. The composite can be formed by adding an encapsulant CTE modifier to a bulk encapsulant before extrusion or casting, layering an encapsulant CTE modifier with thinner sheets of bulk encapsulant and impregnating it not the bulk encapsulant during vacuum lamination, coating and/or impregnating an encapsulant CTE modifier during extrusion of the bulk encapsulant, or in a separate off line process. The encapsulant CTE modifier is substantially evenly distributed through the composite encapsulant thickness and interacts with the bulk encapsulant to reduce the effective CTE of the composite encapsulant below that of the bulk encapsulant.

Although the foregoing invention has been described in some detail for purposes of clarity of understanding, it will be apparent that certain changes and modifications may be practiced within the scope of the invention. It should be noted that there are many alternative ways of implementing both the processes and apparatuses of the present invention. Accordingly, the present embodiments are to be considered as illustrative and not restrictive, and the invention is not to be limited to the details given herein.

What is claimed is:

1. A photovoltaic module comprising:
a light transmissive front layer;
a back layer; and
a plurality of interconnected photovoltaic cells disposed between the light transmissive front layer and the back layer; and
a composite encapsulant interposed between the plurality of solar cells and the light transmissive front layer, the composite encapsulant comprising,
a bulk encapsulant transmissive to visible and near visible wavelengths of the solar spectrum and having a base coefficient of thermal expansion (CTE), and
an encapsulant CTE modifier in the bulk encapsulant, the encapsulant CTE modifier substantially evenly distributed through the composite encapsulant thickness, the encapsulant CTE modifier interacting with the bulk encapsulant such that the effective CTE of the composite encapsulant is less than that of the bulk encapsulant.

2. The module of claim 1, comprising at least 25% by weight of the encapsulant CTE modifier with the bulk encapsulant in the composite encapsulant.

3. The module of claim 1, comprising at least 30% by weight of the encapsulant CTE modifier with the bulk encapsulant in the composite encapsulant.

4. The module of claim 1, wherein the encapsulant CTE modifier is substantially uniformly distributed through at least 50% of the composite encapsulant thickness.

5. The module of claim 1, wherein the encapsulant CTE modifier is substantially uniformly distributed through at least 75% of the composite encapsulant thickness.

6. The module of claim 1, wherein the encapsulant CTE modifier is distributed substantially uniformly throughout the bulk encapsulant.

7. The module of claim 1, wherein the encapsulant CTE modifier interacts with the bulk encapsulant such that the effective CTE of the composite encapsulant is at least 25% less than that of the bulk encapsulant.

8. The module of claim 1, wherein the encapsulant CTE modifier interacts with the bulk encapsulant such that the effective CTE of the composite encapsulant is at least 50% less than that of the bulk encapsulant.

9. The module of claim 1, wherein the bulk encapsulant is a polymer.

10. The module of claim 1, wherein the bulk encapsulant comprises a thermoplastic material.

11. The module of claim 1, wherein the bulk encapsulant comprises a thermal polymer olefin (TPO).

12. The module of claim 1, wherein the bulk encapsulant comprises a non-olefin thermoplastic polymer.

13. The module of claim 1, wherein the bulk encapsulant is selected from the group consisting of polyethylene, polypropylene, polybutylene, polyethylene terephthalate (PET), polybutylene terephthalate (PBT), polystyrene, polycarbonates, fluoropolymers, acrylics, ionomers, silicones and combinations thereof.

14. The module of claim 1, wherein the bulk encapsulant is a polyethylene.

15. The module of claim 1, wherein the bulk encapsulant is a linear, low density polyethylene.

16. The module of claim 1, wherein the encapsulant CTE modifier does not substantially alter the optical spectrum of the bulk encapsulant.

17. The module of claim 1, wherein the encapsulant CTE modifier comprises a woven material.

18. The module of claim 1, wherein the encapsulant CTE modifier comprises a non-woven material.

19. The module of claim 1, wherein the encapsulant CTE modifier is a fiber.

20. The module of claim 1, wherein the encapsulant CTE modifier is a material selected from the group consisting of glass, high modulus polyimide, linear high molecular weight polyethylene, light transmissive minerals and combinations thereof.

21. The module of claim 1, wherein the encapsulant CTE modifier is a non-woven glass fiber.

22. The module of claim 1, wherein the encapsulant CTE modifier is a particle.

23. The module of claim 1, wherein the bulk encapsulant further comprises an adhesion promoter to enhance bonding to the encapsulant CTE modifier.

24. The module of claim 23, wherein the adhesion promoter is a siloxane and the encapsulant CTE modifier is glass fiber.

25. The module of claim 1, wherein the encapsulant CTE modifier is treated to enhance bonding to the bulk encapsulant.

26. The module of claim 25, wherein the encapsulant CTE modifier is silynized.

27. The module of claim 1, wherein the effective CTE of the composite encapsulant is within 25% of the light transmissive front layer CTE.

28. The module of claim 1, wherein the light transmissive front layer comprises glass, the bulk encapsulant comprises liner low density polyethylene and the encapsulant CTE modifier comprises non-woven glass fiber.

29. The module of claim 1, wherein the encapsulant CTE modifier is distributed substantially uniformly throughout the bulk encapsulant.

30. The module of claim 6, wherein the effective CTE of the composite encapsulant varies substantially linearly with the volume fraction of the encapsulant CTE modifier in the bulk encapsulant.

31. The module of claim 1, wherein the light transmissive front layer has greater than 50% transmission from about 400-1100 nm.

32. The module of claim 1, wherein the light transmissive front layer has greater than 80% transmission from about 400-1100 nm.

33. A method of making a photovoltaic module, the method comprising:
assembling,
a light transmissive front layer,
a back layer, and
a plurality of interconnected photovoltaic cells disposed between the light transmissive front layer and the back layer;
disposing a composite encapsulant between the plurality of solar cells and the light transmissive front layer, the composite encapsulant comprising,
a bulk encapsulant transmissive to visible and near visible wavelengths of the solar spectrum having a base coefficient of thermal expansion (CTE), and
an encapsulant CTE modifier in the bulk encapsulant, the encapsulant CTE modifier substantially evenly distributed through the composite encapsulant thickness, the encapsulant CTE modifier interacting with the bulk encapsulant such that the effective CTE of the composite encapsulant is less than that of the bulk encapsulant; and
laminating the assembly.
